(19) United States
(12) Patent Application Publication
(10) Pub. No.: US 2015/0162230 A1
(43) Pub. Date: Jun. 11, 2015

(54) APPARATUS FOR SELF-CENTERING PRE-HEAT RING

(71) Applicant: APPLIED MATERIALS, INC., Santa Clara, CA (US)

(72) Inventors: Kevin Joseph BAUTISTA, San Jose, CA (US); Richard O. COLLINS, Santa Clara, CA (US); Nyi O. MYO, San Jose, CA (US)

(21) Appl. No.: 14/520,957

(22) Filed: Oct. 22, 2014

Related U.S. Application Data
(60) Provisional application No. 61/913,245, filed on Dec. 6, 2013.

(51) Int. Cl. H01L 21/68; C30B 25/10; C30B 25/12; C30B 25/08

(52) U.S. Cl. CPC H01L 21/68; C30B 25/08; C30B 25/10; C30B 25/12

(57) ABSTRACT

Embodiments described herein generally relate to an apparatus for aligning a preheat member. In one embodiment, an alignment assembly is provided for a processing chamber. The alignment assembly includes a lower liner, a preheat member; an alignment mechanism formed on a bottom surface of the preheat member; and an elongated groove formed in a top surface of the lower liner and configured to engage with the alignment mechanism.

### CROSS-REFERENCE TO RELATED APPLICATIONS

This application claims benefit of U.S. Provisional Application Ser. No. 61/913,245 filed Dec. 6, 2013 (Attorney Docket No. APPM/21314USL), of which is incorporated by reference in its entirety.

### BACKGROUND

1. Field

Embodiments of the present invention generally relate to a preheat member in a plasma processing chamber.

2. Description of the Related Art

Semiconductor substrates are processed for a wide variety of applications, including the fabrication of integrated devices and micro-devices. One method of processing substrates includes depositing a material, such as a dielectric material or a conductive metal, on an upper surface of the substrate. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a support, and thermally decomposing the process gas to deposit a material from the gas onto the substrate surface.

The most common epitaxial film deposition reactors used in modern silicon technology are similar in design. Besides substrate and process conditions, however, the design of the deposition reactor (i.e., processing chamber) is essential for film quality in epitaxial growth which uses the precision of gas flow in film deposition. The design of the susceptor support assembly and the preheat member disposed in the deposition reactor influences epitaxial deposition uniformity. In epitaxial processing of silicon carbide particulate (SiCP), the thickness uniformity is adversely affected by variations in a gap distance between the susceptor and the preheat member. A small misalignment of the preheat member during installation or movement of the preheat member due to thermal expansion (e.g. walking) causes an asymmetric gap between the susceptor and the preheat member. The asymmetric gap results in a “tilted” deposition pattern on a substrate undergoing epitaxial processing where deposition one side of substrate is thicker than the other side.

Therefore, there is a need for an improved uniformity in the gap between the preheat member and the susceptor which provides for uniform deposition.

### SUMMARY

Embodiments described herein generally relate to an apparatus for aligning a preheat member, and an deposition reactor having the same. In one embodiment, an apparatus for aligning a preheat member is in the form of an alignment assembly. The alignment assembly includes an alignment mechanism disposed in an elongated radially aligned groove. The alignment mechanism and groove are disposed between a bottom surface of the preheat member and a top surface of the lower liner. The alignment mechanism and groove are configured to restrain the preheat member from moving azthumally and/or rotationally relative to the lower liner.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of a process chamber.

FIG. 2 illustrates a top plan view of the processing chamber of FIG. 1 with the upper dome removed and showing an alignment assembly for a preheat member and lower liner in phantom.

FIG. 3 is a cross-sectional view showing the alignment assembly of FIG. 2.

FIG. 4 illustrates a groove design in the lower liner for the alignment assembly of FIG. 3.

FIG. 5 illustrates an alignment mechanism in the preheat member for the alignment assembly of FIG. 3.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, for purposes of explanation, numerous specific details are set forth in order to provide a thorough understanding of the embodiments of the present disclosure. In some instances, well-known structures and devices are shown in block diagram form, rather than in detail, in order to avoid obscuring the present disclosure. These embodiments are described in sufficient detail to enable those skilled in the art to practice the invention, and it is to be understood that other embodiments may be utilized and that logical, mechanical, electrical, and other changes may be made without departing from the scope of the disclosure.

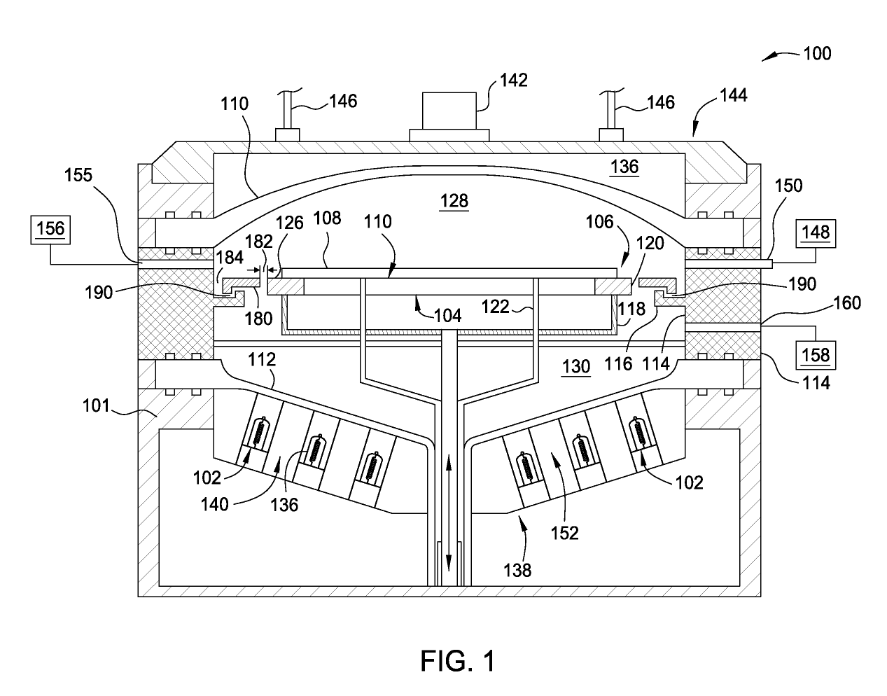

FIG. 1 illustrates a schematic view of a processing chamber 100 having an alignment assembly 190. The processing chamber 100 may be used to process one or more substrates 108, including the deposition of a material on an upper surface of the substrate 108. The processing chamber 100 may include an array of radiant heating lamps 102 for heating, among other components, a back side 104 of a susceptor support assembly 106 and a preheat member 180, which may be a ring, a rectangular member, or a member having any convenient shape, disposed within walls 101 of the processing chamber 100.

The processing chamber 100 includes an upper dome 110, a lower dome 112 and a lower liner 114 that is disposed between the upper dome 110 and lower dome 112. The upper and lower domes 110, 112 generally define an internal region of the processing chamber 100. In some embodiments, the array of radiant heating lamps 102 may be disposed over the upper dome 110.

In general, the central window portion of the upper dome 110 and the bottom of the lower dome 112 are formed from an optically transparent material such as quartz. One or more lamps, such as an array of lamps 102, can be disposed adjacent to and beneath the lower dome 112 in a specified, optimal desired manner around the susceptor support assembly 106 to independently control the temperature at various regions of the substrate 108 as the process gas pass thereover, thereby facilitating the deposition of a material onto the upper surface of the substrate 108. While not discussed here in detail, the deposited material may include gallium arsenide, gallium nitride, aluminum gallium nitride, and the like.

The lamps 102 may be configured to include bulbs 136 and be configured to heat the interior of the processing chamber 100 to a temperature within a range of about 200 degrees Celsius to about 1600 degrees Celsius. Each lamp 102 is coupled to a power distribution board (not shown) through which power is supplied to each lamp 102. The lamps 102 are positioned within a lamphead 138 which may be cooled during or after processing by, for example, a cooling fluid introduced into channels 140, 152 located between the lamps 102. The lamphead 138 conductively and radiatively cools the lower dome 112 due in part to the close proximity of the lamphead 138 to the lower dome 112. The lamphead 138 may also cool the lamp walls and walls of the reflectors (not shown) around the lamps. Alternatively, the lower dome 112 may be cooled by a convective approach known in the industry. Depending upon the application, the lampheads 138 may or may not be in contact with the lower dome 112.

A reflector 144 may be optionally placed outside the upper dome 110 to reflect infrared light that is radiating off the substrate 108 back onto the substrate 108. The reflector 144 may be fabricated from a metal such as aluminum or stainless steel. The efficiency of the reflection can be improved by coating a reflector area with a highly reflective coating such as with gold. The reflector 144 can be coupled by one or more channels 146 to a cooling source (not shown). The channel 146 connects to a passage (not shown) formed on a side of or in the reflector 144. The passage is configured to carry a flow of a fluid such as water and may run along the side of the reflector 144 in any desired pattern covering a portion or entire surface of the reflector 144 for cooling the reflector 144.

The internal volume of the processing chamber 100 is divided into a process gas region 128 that is above the preheat member 180 and substrate 108, and a purge gas region 130 below the preheat member 180 and the susceptor support assembly 106. Process gas supplied from a process gas supply source 148 is introduced into the process gas region 128 through a process gas inlet 150 formed in the sidewall of the lower liner 114. The process gas inlet 150 is configured to direct the process gas in a generally radially inward direction. During the film formation process, the susceptor support assembly 106 may be located in the processing position, which is adjacent to and at about the same elevation as the process gas inlet 150, allowing the process gas to flow along a flow path defined across an upper surface of the substrate 108 in a laminar fashion. The process gas exits the process gas region 128 through a gas outlet 155 located on the side of the processing chamber 100 opposite the process gas inlet 150. Removal of the process gas through the gas outlet 155 may be facilitated by a vacuum pump 156 coupled thereto. As the process gas inlet 150 and the gas outlet 155 are aligned to each other and disposed approximately at the same elevation, it is believed that such a parallel arrangement, when combing with a flatter upper dome 110 will enable a generally planar, uniform gas flow across the substrate 108.

Purge gas may be supplied from a purge gas source 158 to the purge gas region 130 through an optional purge gas inlet 160 (or through the process gas inlet 150) formed in the sidewall of the lower liner 114. The purge gas inlet 160 is disposed at an elevation below the process gas inlet 150. The purge gas inlet 160 is configured to direct the purge gas in a generally radially inward direction. During the film formation process, the preheat member 180 and the susceptor support assembly 106 may be located at a position such that the purge gas flows down and round along a flow path defined across the back side 104 of the susceptor support assembly 106 in a laminar fashion. Without being bound by any particular theory, the flowing of the purge gas is believed to substantially prevent process gas from entering into the purge gas region 130 (i.e., the region under the preheat member 180 and the susceptor support assembly 106). The purge gas exits the purge gas region 130 through a gap 182 formed between the preheat member 180 and the susceptor support assembly 106 and enters the process gas region 128. The purge gas may then exhaust out of the processing chamber 100 through the gas outlet 155.

The susceptor support assembly 106 may include a disk-like susceptor support as shown, or may be a ring-like susceptor support with a central opening and supports the substrate 108 from the edge of the substrate to facilitate exposure of the substrate to the thermal radiation of the lamps 102. The susceptor support assembly 106 includes a susceptor support 118 and a susceptor 120. The susceptor support assembly 106 may be formed from silicon carbide or graphite coated with silicon carbide to absorb radiant energy from the lamps 102 and conduct the radiant energy to the substrate 108.

The lower liner 114 may be fabricated from a quartz material and have a lip 116 configured to accept the preheat member 180 deposed thereon. A space 184 may be provided between the lip 116 on the lower liner 114 and the preheat member 180. The alignment assembly 190 may uniformly maintain the space 184 by centering the preheat member 180 on the lip 116 of the lower liner 114. The space 184 may provide thermal isolation between the lower liner 114 and the preheat member 180. Additionally, the space 184 may allow the preheat member 180 to expand (and contract) due to temperature changes without interference from the lower liner 114.

The preheat member 180 may be fabricated from a silicon carbide (SiC) material and have an inner perimeter configured to accept the susceptor support assembly 106 as well as the space 184 between them. The preheat member 180 is further configured to control the dilution of the process gas by the bottom purge gas by maintaining a uniform width across the gap 182. In epitaxial processing for SiCP films, the bottom purge gases have a large dilution effect on the process gases. In one embodiment, the epitaxial processes process gas flow is in the range of about 30-40 SLM and the bottom purge gases are about 5 SLM. In another embodiment for SiCP processes, the epitaxial processes process gas flow is in the range of about 5 SLM and the bottom purge gases are about 5 SLM. The ratio between the top and bottom gases may be nearly equal. The primary path for bottom gases to reach the topside is between the gap 182 defined between the susceptor support assembly 106 and the preheat member 180. Thus, the bottom purge gases are more inclined to dilute the topside process gases.

The preheat member 180 may be configured to form the gap 182 between the preheat member 180 and the susceptor support assembly 106 to control the dilution of the process gas by the purge gas. The size of the gap 182 may change when the preheat member 180 moves due to thermal expansion. The size of the gap 182 between the preheat member 180 and the susceptor support assembly 106 directly controls how much affect the bottom purge has on the top side gas flow. In one embodiment, the gap 182 may have a distance of about 0.015 inches.

The preheat member 180 may move significantly during thermal cycling and the movement may be compounded after the installation of a cold preheat member 180 in the processing chamber 100. In conventional processing chambers, movement of the preheat ring is inclined to occur radially, rotationally and azthumally. When the preheat ring moves and is no longer concentrically centered with the susceptor, an asymmetric gap may form between the susceptor and the preheat ring (assuming the susceptor is rotating perfectly centered), which results in a “tilted” deposition thickness on one side of the substrate relative to the other. To ensure during thermal expansion the preheat member 180 can thermally expand and contract while maintaining concentricity with the susceptor support assembly 106, the alignment assembly 190 is provided between the preheat member 180 and the lip 116 of the lower liner 114.

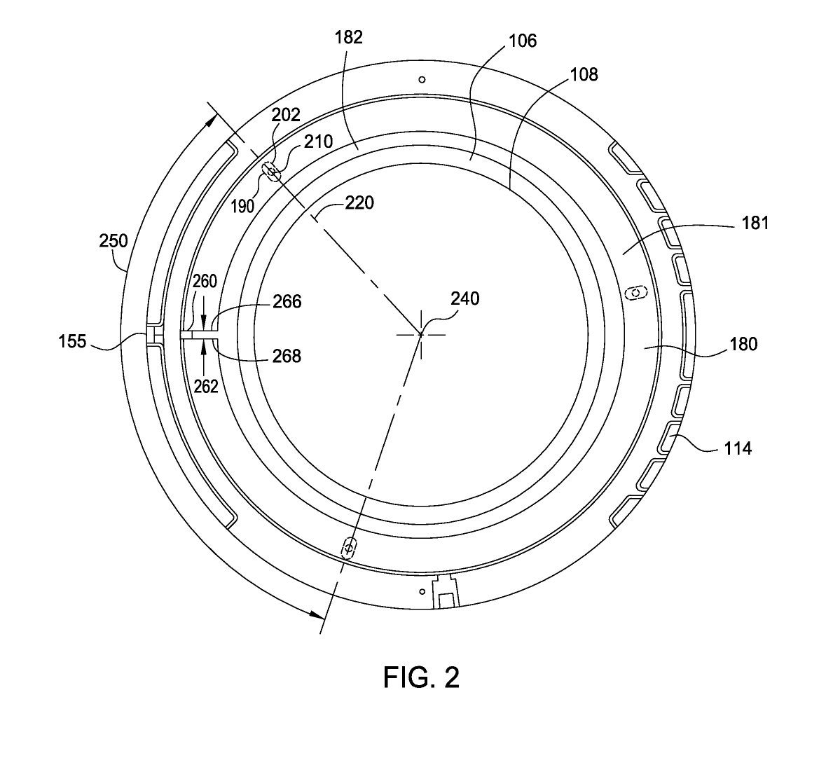

FIG. 2 illustrates a top plan view of the processing chamber 100, with the upper dome removed showing a plurality of alignment assemblies 190 (in phantom) for the preheat member 180 and the lower liner 114. The preheat member 180 has a centerline 240. The centerline 240 of the preheat member 180 may be coincident with a center of the susceptor support assembly 106, which results in the gap 182 having a uniform with defined between the preheat member 180 and the susceptor support assembly 106.

The preheat member 180 may also have a slot 260 formed in the ring. The slot 260 may be formed completely through the preheat member 180 such that first side 266 of the slot 260 does not touch a second side 268 of the slot 260. The slot 260 may have a width 262. The width 262 may be configured to allow the preheat member 180 to expand without inducing thermal stress. The width 262 may additionally be configured to permit purge gasses to pass from the underside of the preheat member 180 to the gas outlet 155 for evacuation from the processing chamber 100.

The alignment assembly 190 may have an alignment mechanism 210 and a groove 202 (both shown in phantom in FIG. 2). The alignment mechanism 210 may be formed in or on the preheat member 180 and the groove 202 may be formed in the lower liner 114. For example, the alignment mechanism 210 may extend from a bottom surface 181 of the preheat member 180 and is configured to mate with the groove 202 formed in a top surface 181 of the preheat member 180. Alternately, the alignment mechanism 210 may be formed in or on the lower liner 114 and the groove 202 may be formed in the preheat member 180. For example, the alignment mechanism 210 may extend from the top surface 117 of the lower liner 114 and is configured to mate with the groove 202 formed in the bottom surface 181 of the preheat member 180. The alignment mechanism 210 may also sit independently and ride in a slot formed from aligned grooves 202 formed in the preheat member 180 and the lower liner 114. In one embodiment, the alignment mechanism 210 is a ball. In another embodiment, the alignment mechanism 210 is a bump or projection. The alignment mechanism 210 and groove 202 restrict the movements of the preheat member 180 relative to the lower liner 114 while still allowing radial movement of the preheat member 180 relative to the centerline 240 of the susceptor support assembly 106 associated with the thermal expansion and contraction of the preheat member 180.

In one embodiment, the alignment mechanism 210 is formed of SiC and is an integral part of the preheat member 180. The alignment mechanism 210 rests in the groove 202 formed in the opaque quartz of the lower liner 214. A major axis of the groove 202 is oriented radially from the center 240 as shown by radial line 220. The alignment mechanism 210 may move radially relative to the centerline 240 within the groove 202 but is prevented from moving laterally, rotationally and azthumally. One or more alignment assemblies 190 may be evenly spaced about the preheat member 180 and the lower liner 114. In one embodiment, three alignment assemblies 190 are evenly spaced about the preheat member 180 and the lower liner 114, for example in a polar array. For example, a spacing 250 for the alignment assemblies 190 may be about 120 degrees apart. Alternatively, the spacing 250 may be irregular. For example, the first alignment assembly 190 may have a spacing 250 of about 100 degrees to a second alignment assembly, the second alignment assembly may have a spacing of about 130 degrees to a third alignment assembly, and the third alignment assembly may have a spacing of about 130 degrees to the first alignment assembly 190.

Although any number of the alignment assemblies 190 may be used, the configuration of the alignment assemblies 190 may affect the gap 182. For example, a single alignment assembly 190 may prevent the preheat member 180 from rotating but not from moving and making the gap 182 asymmetrical. Two alignment assemblies 190 may have similar problems of asymmetry in the gap 182 if the alignment assemblies 190 are aligned with each other. Offsetting the alignment assemblies 190, such that the spacing is about 120 degrees, helps to center the preheat member 180 and maintain a symmetrical width across the gap 182. In one embodiment, the preheat member 180 and lower liner 114 have three alignment assemblies 190 which self-center the preheat member 180 relative to the centerline 240, and prevent the preheat member 180 from rotating, moving laterally or azthumally relative to the susceptor support assembly 206.

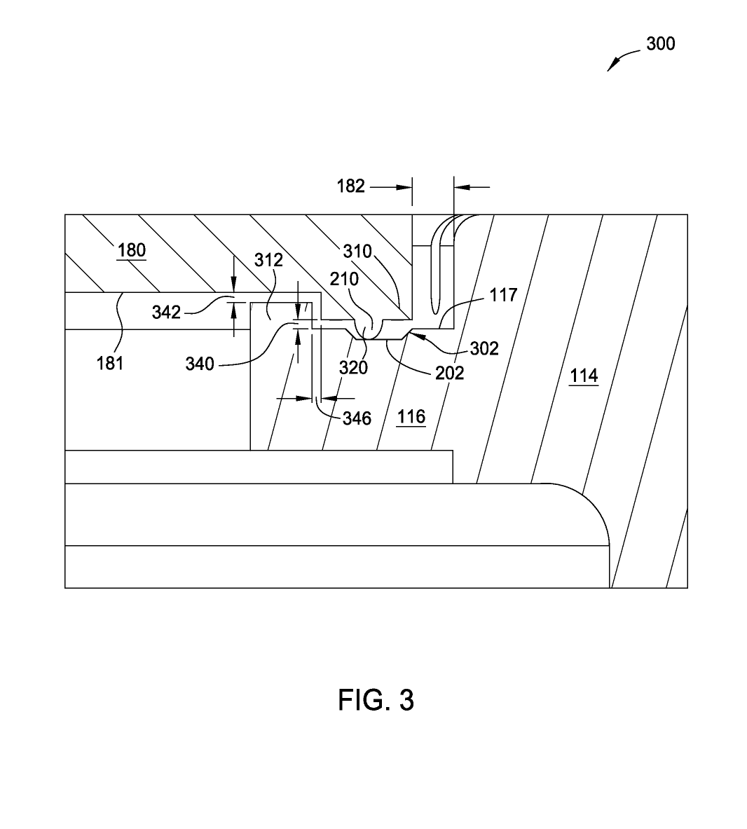

FIG. 3 is a cross-sectional view showing the alignment assembly 190 of FIG. 2. The preheat member 180 has a lip 310 configured to interface with the lip 116 of the lower liner 114. A first gap 342 may be formed between the preheat member 180 and the lip 116 of the lower liner 114 when the alignment mechanism 210 is disposed in the groove 202. A second gap 340 may be formed between the lip 116 of the lower liner 114 and the lip 310 of the preheat member 180. The first gap 342 may be similar in size to the second gap 340 and both gaps 342, 340 may be proportionally related. That is, as the size of the first gap 342 increases, the size of the second gap 340 increases as well. There may be a third gap 346 (and the fourth gap 182) deposed between the preheat member 180 and the lower liner 114. The third and fourth gaps 182, 346 may be inversely proportional. For example, as the preheat member 180 thermally contracts, the size of the third gap 182 may increase while the size of the fourth gap 346 decreases.

Thermally expanding the preheat member 180 causes the alignment mechanism 210 to move toward a far end 303 of the groove 202. Likewise, contraction of the preheat member 180 causes the ball to move away from the far end 303 of the groove 202. The alignment mechanism 210 and the groove 202 are configured such that the thermal expansion and contraction of the preheat member 180 does not cause the alignment mechanism 210 to leave the groove 202. A lip may be formed on the groove 202 such that the preheat member 180 has limited lateral movement. However, the preheat member 180 is still able to move quite substantially radially uniformly about the centerline 240.

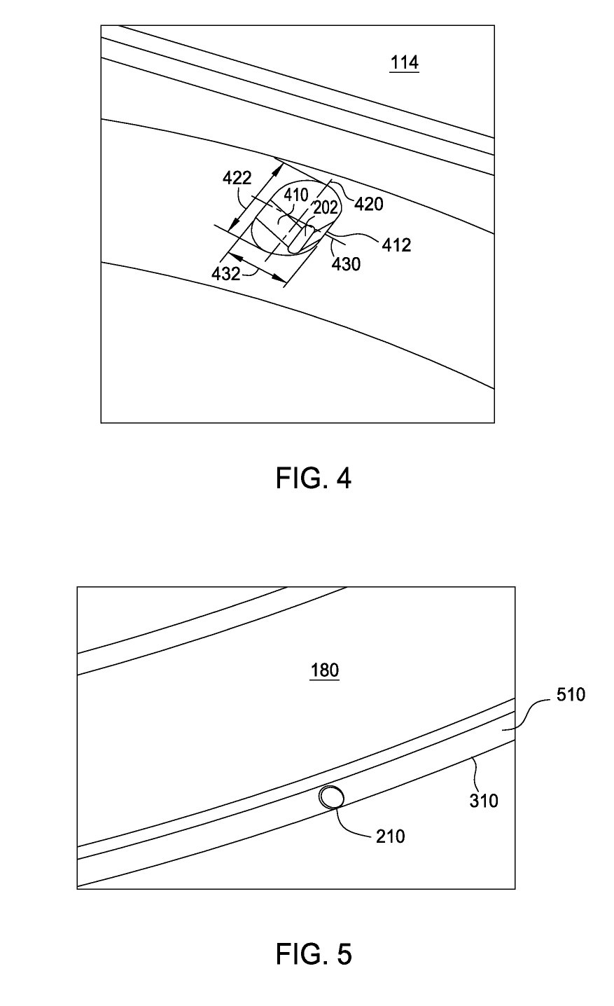

Gap variation caused by thermal expansion and installation setup in conventional deposition reactors can be reduced by the alignment mechanism 210 and groove 202 disposed between the preheat member 180 and the lower liner 114. The alignment mechanism 210 and groove 202 allows for alignment and self-centering of the preheat member 180 relative to the susceptor support assembly 106, thus maintaining a uniform width across the gap 182 which promote uniform deposition results. FIG. 4 illustrates the groove 202 formed in the lower liner 114 of FIG. 3, while FIG. 5 illustrates the alignment mechanism 210 extending from the preheat member 180 of FIG. 3.

The alignment mechanism 210 may be spherical or other suitable shape. Rounded shapes for the alignment mechanism 210 help reduce the contact surface area between the preheat member 180 and the lower liner 114. The reduced contact surface area allows the preheat member 180 to more easily move relative to the lower liner 114. In one embodiment, the alignment mechanism 210 is fabricated from a group comprising silicon nitride, sapphire, zirconia oxide, alumina oxide, quartz, graphite coating, or any other suitable material for use in an epitaxial deposition chamber. In one embodiment, the alignment mechanism 210 has a diameter between about 5 mm and about 15 mm, for example 10 mm. While alignment mechanisms 210 are shown in FIG. 2, it is contemplated that any number of alignment mechanisms 210 may be housed in the preheat member 180. However, three alignment mechanism 210 advantageously contact the points on any plane.

As shown in FIG. 4, the groove 202 may be counter sunk into the lower liner 114 and form an oval shape with a deep-Vee, trapezoidal track or other shape suitably configured to contact and hold the alignment mechanism 210 on at least two contact points. The groove 202 has a minor axis 430. The minor axis 430 has a dimension 432 which is sized to hold the alignment mechanism 210 while providing the gaps 342, 340 (as shown in FIG. 3) between the preheat member 180 and the lower liner 114. The walls 410 of the groove 202 may be flat to promote a single point of contact between the alignment mechanism 210 and each wall 410 of the groove 202. In this manner, heat transfer is minimized between the preheat member 180 and the lower liner 114, which advantageously allows for faster heating and cooling of the preheat member 180, which corresponding allows for faster and more precise temperature control of the substrate. Alternatively, the walls 410 may be curved to better support the alignment mechanism 210.

The groove 202 is elongated and has a major axis 420 aligned radially with the centerline 240. The groove 202 may have a size 422 configured to allow the alignment mechanism 210 to move in the groove 202 while the preheat member 180 thermally expands and contracts. As the alignment mechanism 210 moves in the groove 202, the sides of the alignment mechanism 210 contact the walls 410 of the groove 202 to keep the preheat member 180 from rotating. At least two alignment assemblies 190 which are not aligned in a common diameter will substantially prevent the preheat member 180 from becoming misaligned with the susceptor support assembly 106 (i.e., will maintain uniformity across the gap 182).

The preheat member 180 has a spherically shaped alignment mechanism 210 that inserts into a V-groove 202 countersunk into the lower liner 114. A plurality of alignment assemblies 190, each having a alignment mechanism 210 and a groove 202, positioned around the diameter of the lower liner, and in one example, are about 120 degrees apart. The alignment assemblies 190 allow the preheat member 180 and the lower liner 114 to thermally expand and cool with repeatability. The alignment assemblies 190 eliminates the preheat member 180 from walking laterally, azthumally or rotationally, during thermal processing cycles.

While the foregoing is directed to embodiments of the present invention, other and further embodiments of the invention may be devised without departing from the basic scope thereof, and the scope thereof is determined by the claims that follow.

What is claimed is:

1. An alignment assembly for a processing chamber, comprising:
a lower liner having a lip;
a preheat member having a bottom surface;
an alignment mechanism extending from the bottom surface of the preheat member; and
an elongated groove formed in a top surface of the lip and configured to accept the alignment mechanism.

2. The alignment assembly of claim 1, wherein the alignment mechanism is an integral part of the preheat member.

3. The alignment assembly of claim 1, wherein the preheat member and lower liner have three alignment assemblies which self-center the preheat member relative to a centerline of the lower liner.

4. The alignment assembly of claim 3, wherein the alignment mechanism is a ball.

5. The alignment assembly of claim 1, further comprising:
a first gap formed between the preheat member and the lip of the lower liner when the alignment mechanism is disposed in the groove.

6. The alignment assembly of claim 1, wherein the elongated groove is an oval shape with a deep-Vee.

7. The alignment assembly of claim 1, wherein the elongated groove is an oval shape with a trapezoidal track.

8. An alignment assembly for a processing chamber, comprising:
a lower liner having a lip;
a preheat member having a bottom surface;
an alignment mechanism extending from a top surface of the lip; and
an elongated groove formed in the bottom surface of the preheat member and configured to accept the alignment mechanism.

9. The alignment assembly of claim 8, wherein the alignment mechanism is an integral part of the lip.

10. The alignment assembly of claim 8, wherein the alignment mechanism sits independently and rides in a slot formed from grooves in the lip aligned with the elongated groove in the preheat member.

11. The alignment assembly of claim 10, wherein the alignment mechanism is a ball.

12. The alignment assembly of claim 8, wherein the preheat member and lower liner have three alignment assemblies which self-center the preheat member relative to a centerline of the lower liner.

13. The alignment assembly of claim 8, further comprising:
a first gap formed between the preheat member and the lip of the lower liner when the alignment mechanism is disposed in the groove.

14. The alignment assembly of claim 8, wherein the elongated groove is an oval shape with a deep-Vee.

15. The alignment assembly of claim 9, wherein the elongated groove is an oval shape with a trapezoidal track.

16. A processing chamber, comprising:
an upper dome;
a lower dome;
a lower liner disposed between the upper dome and the lower dome, wherein the upper dome, lower dome and lower liner define a process gas region;
a susceptor support assembly disposed in the process gas region;
a preheat member disposed on the susceptor support assembly; and
a plurality of alignment assemblies disposed between the preheat member and the lower liner, two of which not on a common diameter, each alignment assembly comprising:
a alignment mechanism; and
an elongated groove radially aligned with a centerline of the susceptor support assembly, the alignment mechanism and groove configured to maintain an uniform gap between the preheat member and the lower liner.

17. The processing chamber of claim 16, further comprising:
a gap formed between the preheat member and the susceptor support assembly when the alignment mechanism is disposed in the groove.

18. The processing chamber of claim 17, wherein the gap is about 0.015 inches.

19. The processing chamber of claim 17, wherein the preheat member is concentric with the susceptor.

20. The processing chamber of claim 16, wherein the preheat member and lower liner have three alignment assemblies which self-center the preheat member relative to a centerline and prevent the preheat member from rotating, moving laterally or azthumally relative to the susceptor support assembly.
